(19) United States
(12) Patent Application Publication
(10) Pub. No.: US 2022/0302160 A1
(43) Pub. Date: Sep. 22, 2022

(54) SEMICONDUCTOR STORAGE DEVICE AND METHOD FOR FABRICATING THE SAME

(71) Applicant: KIOXIA CORPORATION, Tokyo (JP)

(72) Inventors: Hiroyuki YAMASHITA, Yokkaichi Mie (JP); Keiichi SAWA, Yokkaichi Mie (JP); Yasushi NAKASAKI, Yokohama Kanagawa (JP); Takamitsu ISHIHARA, Yokohama Kanagawa (JP); Junichi KANEYAMA, Yokkaichi Mie (JP)

(21) Appl. No.: 17/410,711

(22) Filed: Aug. 24, 2021

(30) Foreign Application Priority Data
Mar. 17, 2021 (JP) 2021-044005

(51) Int. Cl. H01L 27/11582; H01L 27/11519; H01L 27/11556; H01L 27/11565

(52) U.S. Cl. CPC H01L 27/11582; H01L 27/11519; H01L 27/11556; H01L 27/11565

(57) ABSTRACT

According to one embodiment, a semiconductor storage device includes a plurality of electrode films on a substrate alternating with plurality of gaps or insulating layers. A charge storage film is provided on a side surface of each of the plurality of electrode films with a first insulating film placed therebetween. A semiconductor film is provided on a side surface of the charge storage film with a second insulating film placed therebetween. Furthermore, a concentration of a first element in the charge storage film adjacent to each gap or insulating film is higher than a concentration of the first element in the charge storage film adjacent to each electrode film. The first element is one of boron, niobium, or molybdenum.

### CROSS-REFERENCE TO RELATED APPLICATION

This application is based upon and claims the benefit of priority from Japanese Patent Application No. 2021-044005, filed Mar. 17, 2021, the entire contents of which are incorporated herein by reference.

### FIELD

Embodiments described herein relate generally to a semiconductor storage device and a method for fabricating a semiconductor storage device.

### BACKGROUND

In a semiconductor storage device, such as three-dimensional semiconductor memory, it is desired to increase the performance of films, such as a charge storage film used in a memory cell.

### BRIEF DESCRIPTION OF THE DRAWINGS

FIG. 1 is a cross-sectional view showing the structure of a semiconductor storage device of a first embodiment.

FIG. 2 is a perspective view showing the structure of a semiconductor storage device of a first embodiment.

FIG. 3A is a cross-sectional view showing the structure of a semiconductor storage device of a comparative example.

FIG. 3B is a cross-section view showing the structure of a semiconductor storage device of a first embodiment.

FIGS. 4A and 4B are cross-sectional views depicting aspects related to a method for fabricating a semiconductor storage device of a first embodiment.

FIGS. 5A and 5B are cross-sectional views depicting aspects related to a method for fabricating a semiconductor storage device of a first embodiment.

FIGS. 6A and 6B are cross-sectional views depicting aspects related to a method for fabricating a semiconductor storage device of a first embodiment.

FIGS. 7A and 7B are cross-sectional views depicting aspects related to a method for fabricating a semiconductor storage device of a first embodiment.

FIG. 8 is a cross-sectional view showing the structure of a semiconductor storage device of a second embodiment.

FIGS. 9A and 9B are cross-sectional views showing modified example structures of semiconductor storage devices of the second embodiment.

FIGS. 10A and 10B are cross-sectional views depicting aspects related to a method for fabricating a semiconductor storage device of a second embodiment.

FIG. 11 is a cross-sectional view showing the structure of a semiconductor storage device of a third embodiment.

FIG. 12 is a cross-sectional view of an example of the structure of a semiconductor storage device of a third embodiment.

FIGS. 13A and 13B are cross-sectional views of examples of the structure of the semiconductor storage device of the third embodiment.

FIGS. 14A and 14B are cross-sectional views depicting aspects related to a method for fabricating a semiconductor storage device of a third embodiment.

FIGS. 15A and 15B are cross-sectional views depicting aspects related to a method for fabricating a semiconductor storage device of a third embodiment.

FIGS. 16A and 16B are cross-sectional views showing the structure of a semiconductor storage device of a fourth embodiment.

FIG. 17A is a cross-sectional view showing the structure of a semiconductor storage device of a comparative example.

FIG. 17B is a cross-sectional view showing the structure of a semiconductor storage device of a fourth embodiment.

FIGS. 18A and 18B are cross-sectional views depicting aspects related to a method for fabricating a semiconductor storage device of a fourth embodiment.

FIGS. 19A and 19B are cross-sectional views depicting aspects related to a method for fabricating a semiconductor storage device of a fourth embodiment.

FIGS. 20A and 20B are cross-sectional views depicting aspects related to a method for fabricating a semiconductor storage device of a fourth embodiment.

FIGS. 21A and 21B are cross-sectional views depicting aspects related to a method for fabricating a semiconductor storage device of a fourth embodiment.

FIGS. 22A and 22B are cross-sectional views depicting aspects related to a method for fabricating a semiconductor storage device of a fourth embodiment.

FIGS. 23A and 23B are cross-sectional views depicting aspects related to a method for fabricating a semiconductor storage device of a fourth embodiment.

FIGS. 24A and 24B are cross-sectional views depicting aspects related to a method for fabricating a modified example of a semiconductor storage device of a fourth embodiment.

FIGS. 25A and 25B are cross-sectional views depicting aspects related to a method for fabricating a modified example of a semiconductor storage device of a fourth embodiment.

### DETAILED DESCRIPTION

Embodiments provide a semiconductor storage device and a method for fabricating the semiconductor storage device, the device and the method which can increase the performance of certain memory cell films.

In general, according to one embodiment, a semiconductor storage device includes a plurality of electrode films on a substrate alternating with a plurality of gaps or insulating layers. A charge storage film is provided on a side surface of each of the plurality of electrode films with a first insulating film placed therebetween. A semiconductor film is provided on a side surface of the charge storage film with a second insulating film placed therebetween. Furthermore, a concentration of a first element in the charge storage film on adjacent to each gap or insulating film is higher than a concentration of the first element in the charge storage film adjacent to each electrode film. The first element is one of boron, niobium, or molybdenum.

Hereinafter, certain example embodiments of the present disclosure will be described with reference to the drawings. In the drawings, the same elements are denoted by the same reference symbols and overlapping explanations for subsequent examples may be omitted.

### First Embodiment

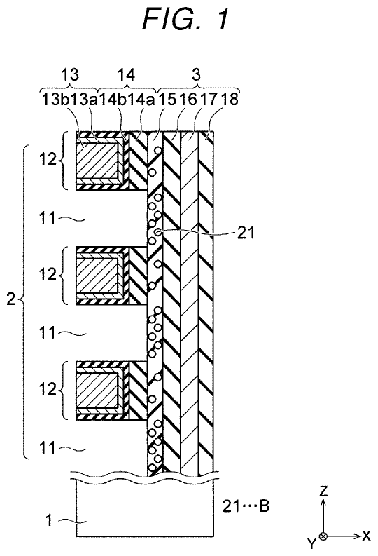

FIG. 1 is a cross-sectional view showing the structure of a semiconductor storage device of a first embodiment. The semiconductor storage device of FIG. 1 is three-dimensional semiconductor memory, for example.

The semiconductor storage device of FIG. 1 includes a substrate 1, a stacked portion 2, and a columnar portion 3. The stacked portion 2 includes a plurality of air gaps 11 (gaps 11 or “gaps”) and a plurality of films 12, and each film 12 includes an electrode film 13 and a block insulating film 14. The columnar portion 3 includes a charge storage film 15, a tunnel insulating film 16, a channel semiconductor film 17, and a core insulating film 18.

The electrode film 13 includes a barrier metal layer 13a and an electrode material layer 13b, and the block insulating film 14 includes an insulating layer 14a and an insulating layer 14b. Furthermore, FIG. 1 schematically shows boron (B) dopants (dopant elements 21) contained in the charge storage film 15.

The substrate 1 is a semiconductor substrate such as a silicon substrate, for example. In the present specification, a +Z direction is referred to as an upward direction, and a −Z direction is referred to as a downward direction. The −Z direction may coincide with the direction of gravity, but the −Z direction does not have to coincide with the direction of gravity.

The stacked portion 2 includes: the plurality of films 12 formed above the substrate 1; and the plurality of air gaps 11. The air gaps 11 and the films 12 are alternately formed/stacked with one another. Each air gap 11 is a space or void filled with air. Each film 12 includes the block insulating film 14 and the electrode film 13.

The columnar portion 3 has a columnar shape (e.g., a cylindrical or pillar shape) extending in the Z direction through the stacked portion 2. The columnar portion 3 includes the charge storage film 15, the tunnel insulating film 16, the channel semiconductor film 17, and the core insulating film 18 which are formed in this order on a side surface of the stacked portion 2. The semiconductor storage device of the first embodiment includes a plurality of columnar portions 3 in the stacked portion 2, but FIG. 1 shows just one of these columnar portions 3.

The block insulating film 14 in each film 12 includes the insulating layer 14a and the insulating layer 14b. The electrode film 13 in each film 12 includes the barrier metal layer 13a and the electrode material layer 13b. The insulating layer 14a, the insulating layer 14b, the barrier metal layer 13a, and the electrode material 13b are formed in this order on a side surface of the charge storage film 15. The insulating layer 14b and the barrier metal layer 13a are formed not only on the side surface of the electrode material layer 13b, but also on the upper surface and the lower surface of the electrode material layer 13b. The barrier metal layer 13a is a titanium nitride (TiN) film, for example. The electrode material layer 13b is a tungsten (W) layer, for example. The insulating layer 14a is a silicon oxide (SiO₂) film, for example. The insulating layer 14b is an aluminum oxide (AlOₓ) film, for example.

The charge storage film 15 is formed on a side surface of each block insulating film 14. The side surface of the charge storage film 15 is also in contact with each air gap 11. The charge storage film 15 is used to store the charge in a memory cell transistor corresponding to the written/stored data. The charge storage film 15 is a silicon nitride (SiN) film, for example. The charge storage film 15 is formed on a side surface of each electrode film 13 with the block insulating film 14 placed therebetween.

The tunnel insulating film 16 is formed on a side surface of the charge storage film 15. The tunnel insulating film 16 is a silicon oxynitride (SiON) film, for example.

The channel semiconductor film 17 is formed on a side surface of the tunnel insulating film 16. The channel semiconductor film 17 functions as a channel of a memory cell transistor or a select transistor. The channel semiconductor film 17 is a polysilicon layer, for example. The channel semiconductor film 17 is formed on the side surface of the charge storage film 15 with the tunnel insulating film 16 placed therebetween.

The core insulating film 18 is formed on a side surface of the channel semiconductor film 17. The core insulating film 18 is a SiO₂ film, for example.

The charge storage film 15, the tunnel insulating film 16, the channel semiconductor film 17, and the core insulating film 18 each include regions located adjacent to (at the same Z direction position as) the films 12 and regions adjacent to (at the same Z direction position as) the air gaps 11. A memory cell (also referred to as a memory cell transistor) of the semiconductor storage device of the first embodiment is formed in the regions adjacent to the films 12. This region can be referred to as a cell portion. The region between the adjacent cell portions is referred to as an inter-cell portion. The charge storage film 15, the tunnel insulating film 16, the channel semiconductor film 17, and the core insulating film 18 each include the cell portions on the adjacent to the films 12 and the inter-cell portion adjacent to the air gaps 11.

In the first embodiment, the charge storage film 15 contains dopant element 21 (boron atoms). It is to be noted that the B concentration in the charge storage film 15 on the side of the air gap 11 is higher than the B concentration in the charge storage film 15 on the side of the film 12. That is, the B concentration in the charge storage film 15 in the inter-cell portion is higher than the B concentration in the charge storage film 15 in the cell portion. FIG. 1 shows a state in which the charge storage film 15 in the inter-cell portion contains the dopant element 21 (a B atom) in high concentrations and the charge storage film 15 in the cell portion contains the dopant element 21 (the B atom) in low concentrations. The B concentration (also referred to as “atomic concentration”) in the charge storage film 15 in the inter-cell portion is 5.0×10²⁰ atoms/cm³ or more, for example. The boron concentration in the charge storage film 15 in the cell portion is 1.0×10¹⁹ atoms/cm³ or more but less than 5.0×10²⁰ atoms/cm³, for example. The charge storage film 15 in the cell portion may contain the dopant element 21 (boron). The charge storage film 15 in the cell portion does not have to contain any dopant element 21 (boron).

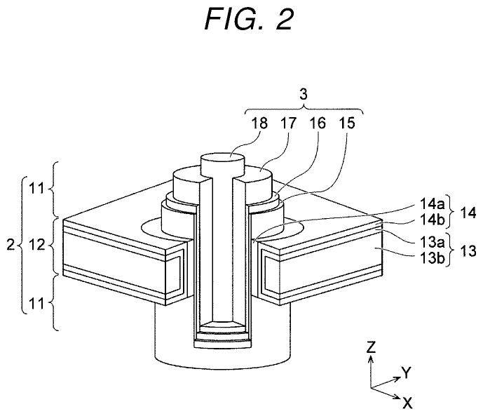

FIG. 2 is a perspective view showing the structure of the semiconductor storage device of the first embodiment.

FIG. 2 shows one film 12 in the stacked portion 2, air gaps 11 formed above and below the film 12, and one columnar portion 3 passing through the film 12. The planar shape of the columnar portion 3 of the present embodiment is circular as shown in FIG. 2. The core insulating film 18 is placed in the central part of the columnar portion 3, and the channel semiconductor film 17, the tunnel insulating film 16, and the charge storage film 15 surround the core insulating film 18 in a circular manner.

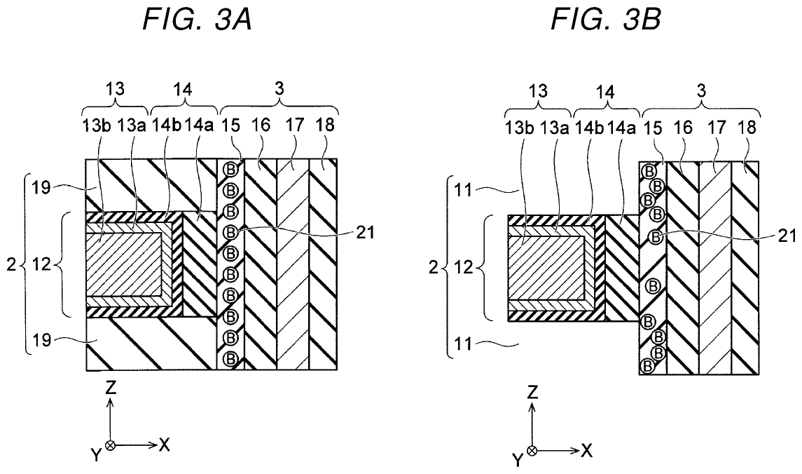

FIGS. 3A and 3B are cross-sectional views showing the structure of a semiconductor storage device of a comparative example of the first embodiment and the structure of the semiconductor storage device of the first embodiment.

FIG. 3A shows the structure of the semiconductor storage device of the above-mentioned comparative example. The semiconductor storage device of this comparative example includes an insulating film 19 in place of the air gap 11. The insulating film 19 is a SiO₂ film, for example. Furthermore, in this comparative example, the boron concentration in the charge storage film 15 portion adjacent to the insulating film 19 is equal to the boron concentration in the charge storage film 15 portion adjacent to the film 12. That is, the boron concentration in the charge storage film 15 in the inter-cell portion is equal to the boron concentration in the charge storage film 15 in the cell portion.

According to this comparative example, by adding the dopant element 21 (boron) in the charge storage film 15 in the inter-cell portion, it is possible to lower the dielectric constant of the charge storage film 15 in the inter-cell portion and reduce the capacitance of the inter-cell portion. This makes it possible to prevent interference between the memory cells and curb the spread of the distribution of the threshold voltages of the memory cells.

On the other hand, the charge storage film 15 in the cell portion of this comparative example contains the dopant element 21 (boron) whose concentration is equal to the concentration of the dopant element 21 (boron) in the charge storage film 15 in the inter-cell portion. When the charge storage film 15 in the cell portion contains a high concentration of the dopant element 21 (boron), a defect is likely to occur in the charge storage film 15 in the cell portion, which results in a dielectric strength failure and a decrease in reliability of the memory cell.

Moreover, an electric field from the electrode film 13 tends to be applied to the charge storage film 15 in the inter-cell portion of this comparative example. Thus, when a memory cell erasing operation is performed, a hole is also injected into the charge storage film 15 in the inter-cell portion and remains as a residual hole. When a memory cell write operation is then performed, the hole injected at the time of erasing operation and an electron written at the time of write operation become electrically neutral. This results in degradation in characteristics of the memory cell or a decrease in the reliability (data retention property) of the memory cell.

FIG. 3B shows the structure of the semiconductor storage device of the first embodiment. In the first embodiment, the boron concentration in the portion charge storage film 15 adjacent the air gap 11 is higher than the boron concentration in the portion charge storage film 15 adjacent the film 12. That is, the B concentration in the charge storage film 15 in the inter-cell portion is higher than the B concentration in the charge storage film 15 in the cell portion.

By adding the dopant element 21 (boron) to the charge storage film 15 in the inter-cell portion in high concentrations, as also in the case of the comparative example, it is possible to lower the dielectric constant of the charge storage film 15 in the inter-cell portion and reduce the capacitance of the inter-cell portion. This makes it possible to prevent interference between the memory cells and curb the spreading of the distribution of the threshold voltages of the memory cells. In the first embodiment, the B concentration in the charge storage film 15 in the inter-cell portion is 5.0×10²⁰ atoms/cm³ or more, for example.

Additionally, the boron concentration in the charge storage film 15 in the cell portion of the first embodiment is lower than the boron concentration in the charge storage film 15 in the inter-cell portion. This makes it possible to prevent a defect from occurring in the charge storage film 15 in the cell portion and thus prevent a dielectric strength failure and a decrease in reliability of the memory cell.

Furthermore, by adding the dopant element 21 (boron) to the charge storage film 15 in the cell portion in low concentrations, it is possible to make the trap level deeper in the charge storage film 15 in the cell portion. This makes it possible to improve the write characteristic and charge retention property of the memory cell. In the first embodiment, the boron concentration in the charge storage film 15 in the cell portion is in a range of 1.0×10¹⁹ atoms/cm³ to 5.0×10²⁰ atoms/cm³, for example.

Moreover, the semiconductor storage device of the first embodiment includes the air gaps 11 in place of the insulating films 19. This makes the electric field from the electrode film 13 even less likely to be applied to the charge storage film 15 in the inter-cell portion. This makes it possible to prevent a residual hole from remaining at the time of memory cell erasing operation and improve the charge retention property of the memory cell.

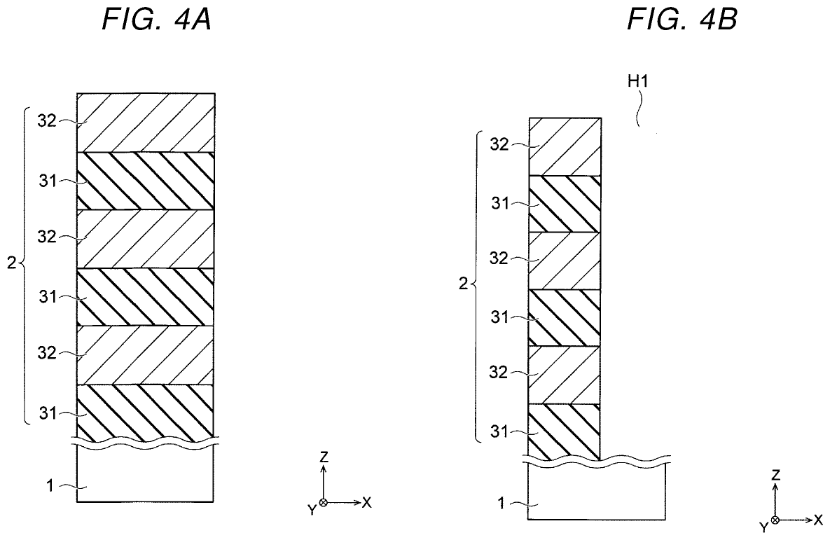

FIGS. 4A to 7B are cross-sectional views showing a method for fabricating the semiconductor storage device of the first embodiment.

First, a plurality of sacrificial films 31 and a plurality of sacrificial films 32 are alternately formed above a substrate 1 (FIG. 4A).

An air gap 11 is formed in place of each sacrificial film 31. The sacrificial film 31 is a silicon (Si) layer having a film thickness of about 30 nm, for example, and is formed by plasma chemical vapor deposition (CVD) using silane (SiH₄) gas.

A film 12 eventually replaces each sacrificial film 32. The sacrificial film 32 is a SiN film having a film thickness of about 30 nm, for example, and is formed by plasma CVD using dichlorosilane (SiH₂Cl₂) gas and ammonia (NH₃) gas.

Next, a memory hole H1 is formed in the sacrificial films 31 and the sacrificial films 32 by lithography and reactive ion etching (RIE) (FIG. 4B). The memory hole H1 is formed into a shape extending in the Z direction. A columnar portion 3 is eventually embedded in the memory hole H1.

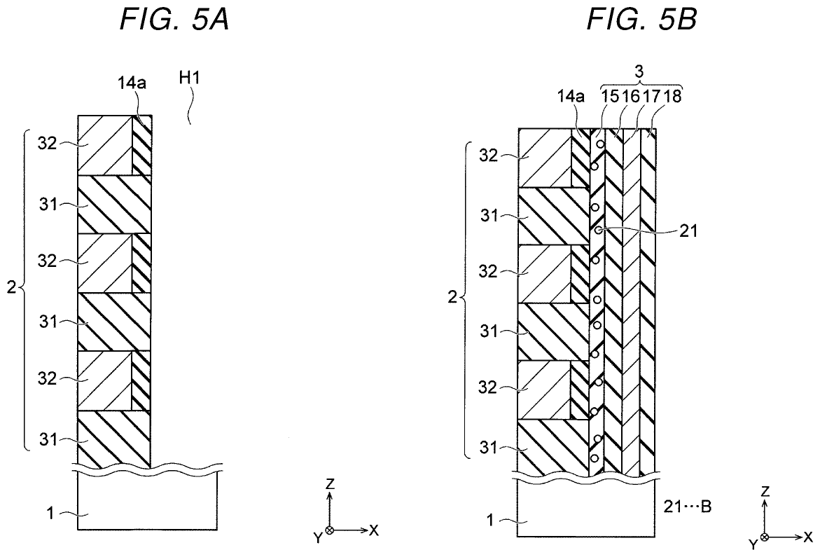

Then, the front surface of each sacrificial film 32, which is exposed by the formation of the memory hole H1, is oxidized (FIG. 5A). This causes a part of each sacrificial film 32 to change to an insulating layer 14a, and the insulating layer 14a is formed in the sacrificial film 32. The insulating layer 14a is a SiO₂ film, for example, and is formed by direct radical oxidation of each sacrificial film 32.

Next, a charge storage film 15, a tunnel insulating film 16, a channel semiconductor film 17, and a core insulating film 18 are formed in order in the memory hole H1 (FIG. 5B) . As a result, the columnar portion 3 is formed in the memory hole H1. The charge storage film 15 is formed on a side surface of each sacrificial film 31 and is formed on a side surface of each sacrificial film 32 with the insulating layer 14a placed therebetween. The channel semiconductor film 17 is formed on a side surface of the charge storage film 15 with the tunnel insulating film 16 placed therebetween.

The charge storage film 15 is a silicon nitride (SiN) film having a film thickness of about 6 nm, for example, and is formed by atomic layer deposition (ALD) in a reduced-pressure environment (2000 Pa or less) at 300° C. to 800° C. using dichlorosilane (SiH₂Cl₂) gas and NH₃ gas. In the present embodiment, the dopant element 21 (boron) is added to the charge storage film 15 by supplying BCl₃ gas during this ALD sequence, or the addition of the dopant element 21 (boron) to the charge storage film 15 is performed by, for example, adding the dopant element 21 (boron) to the front surface of the charge storage film 15 and thermally diffusing the dopant element 21 (boron) in the charge storage film 15. At the stage of FIG. 5B, the B concentration in the charge storage film 15 adjacent the sacrificial film 31 is equal to the B concentration in the charge storage film 15 adjacent the sacrificial film 32. That is, the B concentration in the charge storage film 15 in the inter-cell portion is equal to the B concentration in the charge storage film 15 in the cell portion.

The tunnel insulating film 16 is a silicon oxynitride (SiON) film having a film thickness of about 7 nm, for example, and is formed by ALD in a reduced-pressure environment (2000 Pa or less) at 400° C. to 800° C. using hexachlorodisilane (“HCD”) gas, NH₃ gas, and O₂ gas. The channel semiconductor film 17 is a silicon layer having a film thickness of about 10 nm, for example, and is formed by CVD in a reduced-pressure environment (2000 Pa or less) at 400° C. to 800° C. using silane (SiH₄) gas as precursor. The resulting silicon film can then be crystallized by annealing. This causes this silicon layer to change to a polysilicon layer from an amorphous silicon layer. The core insulating film 18 is a SiO₂ film, for example, and is formed by CVD using tetraethyl orthosilicate (“TEOS”).

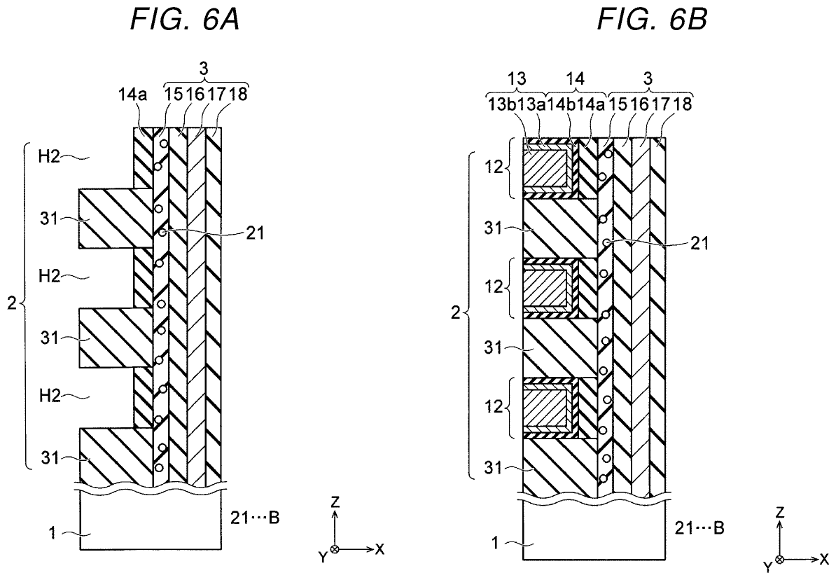

Then, a slit is formed in the sacrificial films 31 and the sacrificial films 32 and the sacrificial films 32 are removed via the slit (FIG. 6A). As a result, a plurality of cavities H2 are formed between the sacrificial films 31, and the insulating layers 14a are exposed in these cavities H2. The sacrificial films 32 are removed by wet etching using hot phosphoric acid, for example.

Next, an insulating layer 14b, a barrier metal layer 13a, and an electrode material layer 13b are formed in order in each cavity H2 from the slit (FIG. 6B). As a result, between the sacrificial films 31, a block insulating film 14 and an electrode film 13 are formed in order on aside surface of the charge storage film 15 and films 12 are formed. In this way, the sacrificial films 32 are replaced with the electrode films 13. The insulating layer 14b is an AlOₓ film having a film thickness of about 3 nm, for example, and is formed by ALD in a reduced-pressure environment (2000 Pa or less) at 200° C. to 500° C. using aluminum trichloride (AlCl₃) gas and ozone (O₃) gas. The barrier metal layer 13a is a titanium nitride (TiN) film, for example, and is formed by CVD using titanium tetrachloride (TiCl₄) gas and ammonia (NH₃) gas. The electrode material layer 13b is a tungsten (W) layer, for example, and is formed by CVD using tungsten hexafluoride (WF₆) gas.

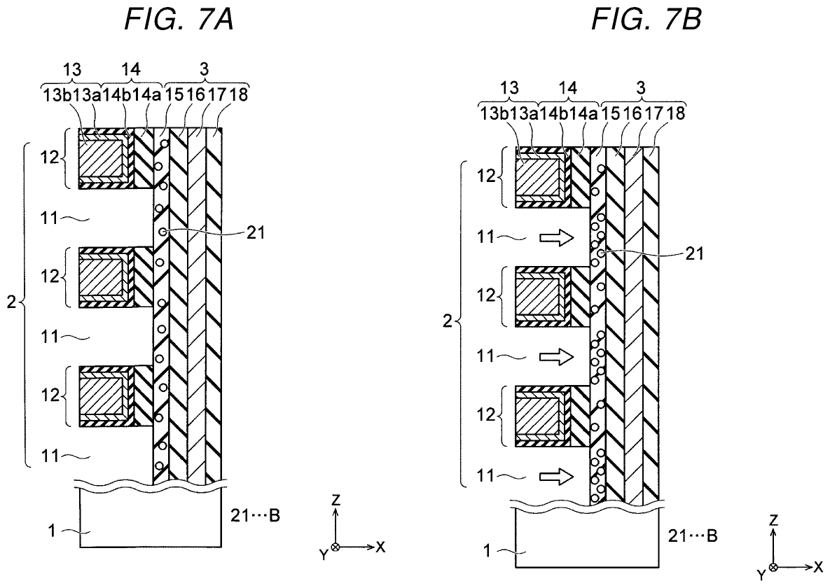

Then, the sacrificial films 31 are removed from the slit (FIG. 7A). As a result, a plurality of air gaps 11 are formed between the films 12 and the charge storage film 15 is exposed in these air gaps 11. The sacrificial films 31 are removed by wet etching using tetramethylammonium hydroxide (TMY), for example.

Next, the dopant element 21 (boron) is added to the charge storage film 15 from the air gaps 11 (FIG. 7B). As a result, the dopant element 21 (boron) is added mainly to the charge storage film 15 portions adjacent to each air gap 11 and the B concentration in the charge storage film 15 facing each air gap 11 is thus higher than the B concentration in the charge storage film 15 portions adjacent to each film 12. That is, the B concentration in the charge storage film 15 in the inter-cell portion is higher than the B concentration in the charge storage film 15 in the cell portion.

In the process of FIG. 7B, the dopant element 21 (boron) is added to the charge storage film 15 by supplying gas containing the dopant element 21 (boron) to the air gaps 11 from the slit. This gas is BCl₃ gas, for example. In the process of FIG. 7B, the addition of the dopant element 21 (boron) to the charge storage film 15 is performed by, for example, making BCl₃ molecules adsorb onto the front surface of the charge storage film 15 by vapor phase adsorption from an atmosphere of BCl₃ gas and thermally diffusing the B element 21 in the BCl₃ molecules into the charge storage film 15. This thermal diffusion is performed by annealing at 900° C. or higher, for example. In the process of FIG. 7B, the addition of the dopant element 21 (boron) to the charge storage film 15 may be performed by radical annealing using B₂H₆ gas and H₂ gas, for example. As a result, the B concentration in the charge storage film 15 in the inter-cell portion is 5.0×10²⁰ atoms/cm³ or more, for example. Moreover, the B concentration in the charge storage film 15 in the cell portion is 1.0×10¹⁹ atoms/cm³ to 5.0×10²⁰ atoms/cm³, for example. As described above, it is possible to make the boron concentration in the portion of the charge storage film 15 formed on the side surface of each sacrificial film 31 higher than the boron concentration in the portion of the charge storage film 15 formed on the side surface of each sacrificial film 32. In a region in which the sacrificial film 31 is formed, the air gap 11 is formed by the removal of the sacrificial film 31. In a region in which the sacrificial film 32 is formed, the film 12 is eventually formed after the removal of the sacrificial film 31.

Then, various insulating films, wiring layers, plug layers, and the like are formed on the substrate 1. For example, the slit mentioned above is filled with an insulating film. In this way, the semiconductor storage device of the present embodiment is fabricated.

As described above, the charge storage film 15 of the first embodiment is formed such that the boron concentration in the portion of the charge storage film 15 adjacent the air gap 11 is higher than the boron concentration in the portion of the charge storage film 15 adjacent the film 12 . Thus, according to the first embodiment, as described with reference to FIGS. 3A and 3B, it is possible to increase the performance of the charge storage film 15.

### Second Embodiment

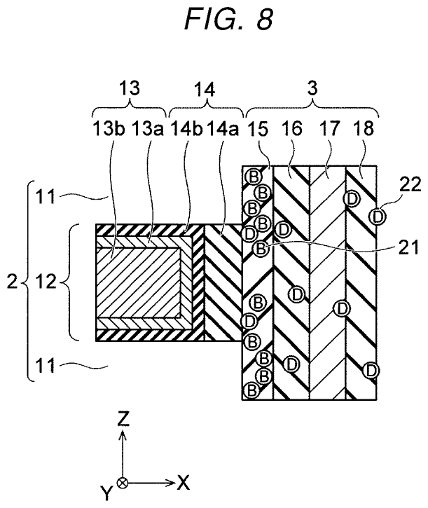

FIG. 8 is a cross-sectional view showing the structure of a semiconductor storage device of a second embodiment.

In addition to the same aspects as those of the semiconductor storage device of the first embodiment, the semiconductor storage device of the second embodiment includes a deuterium (D) dopant (dopant element 22 (D)) in columnar portions 3. FIG. 8 schematically shows the inclusion of these deuterium dopant elements 22.

The dopant element 22 (deuterium) may be contained in each or any of a charge storage film 15, a tunnel insulating film 16, a channel semiconductor film 17, a core insulating film 18, an interface between the charge storage film 15 and the tunnel insulating film 16, an interface between the tunnel insulating film 16 and the channel semiconductor film 17, and an interface between the channel semiconductor film 17 and the core insulating film 18. Furthermore, the dopant element 22 (deuterium) may be contained in a block insulating film 14 or an interface between the block insulating film 14 and the charge storage film 15. According to the second embodiment, the dopant element 22 (deuterium) increases the reliability of the memory cell.

The columnar portion 3 may contain a hydrogen (H) element as an impurity in addition to the dopant element 22 (deuterium). It is preferable that, in an area containing the deuterium and the hydrogen, the deuterium concentration be higher than the hydrogen concentration. For example, when the charge storage film 15 contains the dopant element 22 (deuterium) and the hydrogen atoms, the deuterium concentration in the charge storage film 15 is preferably higher than the hydrogen concentration in the charge storage film 15. Likewise, when an interface between the charge storage film 15 and the tunnel insulating film 16 contains the dopant element 22 (deuterium) and the H element, it is preferable that the D concentration at the interface is higher than the H concentration at the interface.

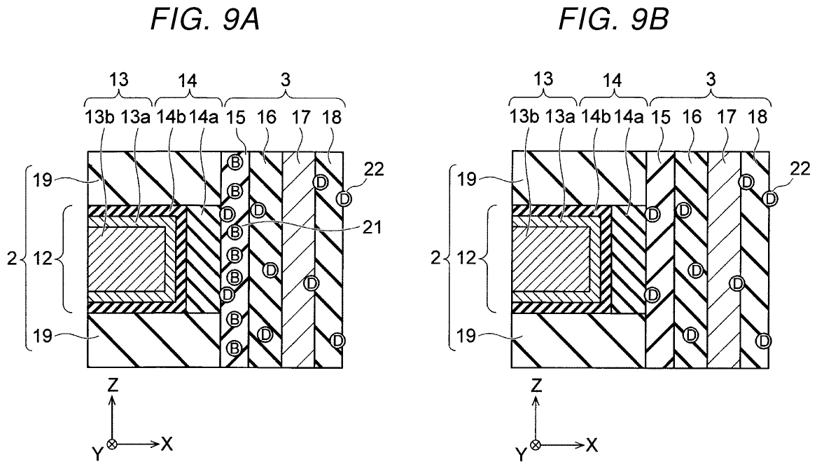

FIGS. 9A and 9B are cross-sectional views showing the structures of semiconductor storage devices of modified examples of the second embodiment.

In a first modified example shown in FIG. 9A, a stacked portion 2 includes an insulating film 19 in place of an air gap 11 and the B concentration in a charge storage film 15 adjacent to the insulating film 19 is equal to the B concentration in the charge storage film 15 adjacent to a film 12. Thus, the semiconductor storage device of the present modified example has a structure obtained by adding the dopant element 22 (deuterium) to the semiconductor storage device (FIG. 3A) of the above-mentioned comparative example. As described above, the distribution of the dopant element 22 (deuterium) of the present embodiment may be applied together with the distribution of the dopant element 21 (boron) of the first embodiment or may be applied together with the distribution of the dopant element 21 (boron) of the above comparative example.

In a second modified example shown in FIG. 9B, a stacked portion 2 includes an insulating film 19 in place of an air gap 11 and a charge storage film 15 does not contain the dopant element 21 (boron) . Thus, the semiconductor storage device of the present modified example has a structure obtained by removing the dopant element 21 (boron) from the semiconductor storage device of the first modified example. As described above, the distribution of the dopant element 22 (deuterium) of the present embodiment may be applied to a semiconductor storage device without the dopant element 21 (boron).

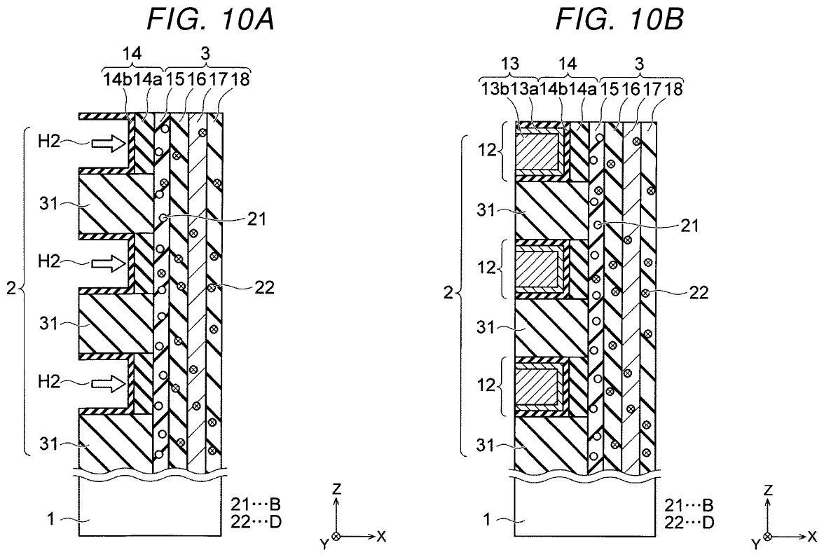

FIGS. 10A and 10B are cross-sectional views showing a method for fabricating the semiconductor storage device of the second embodiment.

First, the processes of FIGS. 4A to 6A are performed. Then, after an insulating layer 14b is formed in each cavity H2 from the slit mentioned above, radical-assisted annealing is performed (FIG. 10A). As a result, the dopant element 22 (deuterium) is added to the columnar portion 3 from each cavity H2.

The above-mentioned annealing is performed using mixed gas containing deuterium (D₂) gas or deuterium oxide (D₂O) gas, for example. This mixed gas may further contain oxygen (O₂) gas, helium (He) gas, neon (Ne) gas, argon (Ar) gas, krypton (Kr) gas, xenon (Xe) gas, or radon (Rn) gas. In the above-mentioned annealing, deuterium plasma is generated from D2 gas or D₂O molecules and the deuterium plasma enter the columnar portion 3 from each cavity H2, whereby the dopant element 22 (deuterium) is added to the columnar portion 3. In so doing, the above-mentioned annealing may be performed with the assistance of not only radical components, but also ion components.

The above-mentioned annealing is performed at 800° C. for 30 seconds, for example. According to the second embodiment, by performing radical-assisted annealing, it is possible to add the dopant element 22 (deuterium) to the columnar portion 3 in a short time. For example, when the dopant element 22 (deuterium) is added by D2 (heavy hydrogen gas) annealing, by performing this annealing at 700° C. to 900° C. for 30 minutes, the dopant element 22 (deuterium) can be added to the columnar portion 3. In other examples, according to the present embodiment, by performing radical-assisted annealing at 700° C. or higher for 30 seconds, the dopant element 22 (deuterium) can be added to the columnar portion 3.

Then, a barrier metal layer 13a and an electrode material layer 13b are formed in order in each cavity H2 from the slit mentioned above (FIG. 10B). As a result, between the sacrificial films 31, a block insulating film 14 and an electrode film 13 are formed in order on a side surface of the charge storage film 15 and films 12 are formed. In this way, the sacrificial films 32 are replaced with the electrode films 13. The dopant element 22 (deuterium) of the present embodiment is added to the columnar portion 3 before the electrode film 13 is formed in the space (the cavity H2) left by the removal of the sacrificial film 32.

Next, the processes of FIGS. 7A and 7B are performed. Then, various insulating films, wiring layers, plug layers, and the like are formed on the substrate 1. For example, the slit mentioned above is filled with an insulating film. In this way, the semiconductor storage device of the second embodiment is fabricated.

As described above, the columnar portion 3 of the second embodiment contains the dopant element 22 (deuterium). According to the second embodiment, the dopant element 22 (deuterium) increases the reliability of the memory cell. Furthermore, according to the second embodiment, by adding the dopant element 22 (deuterium) by radical-assisted annealing, it is possible to add the dopant element 22 (deuterium) in a short time.

### Third Embodiment

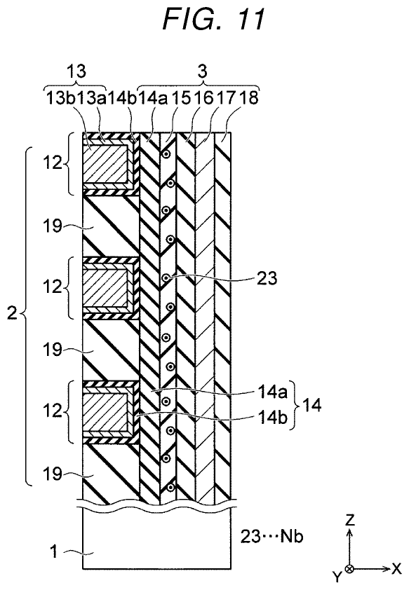

FIG. 11 is a cross-sectional view showing the structure of a semiconductor storage device of a third embodiment.

The semiconductor storage device of the third embodiment includes a plurality of insulating films 19 in place of the plurality of air gaps 11 of the semiconductor storage device of the first embodiment. The insulating film 19 is a SiO₂ film, for example.

Moreover, the semiconductor storage device of the third embodiment includes an insulating layer 14a as part of a columnar portion 3 instead of an insulating layer 14a on each film 12. That is, the insulating layer 14a is continuous along the length of the columnar portion 3 instead being provided in discrete portions separated from one another. In the third embodiment, the insulating layer 14a, a charge storage film 15, a tunnel insulating film 16, a channel semiconductor film 17, and a core insulating film 18 are formed in order on a side surface of each of the plurality of insulating films 19 and a plurality of films 12.

Furthermore, the semiconductor storage device of the third embodiment includes niobium (Nb) (dopant element 23) in the charge storage film 15 in place of the dopant element 21 (boron). FIG. 11 schematically shows the inclusion of these niobium dopant elements 23. The niobium concentration in the charge storage film 15 is 1.0'10²¹ atoms/cm³ or less, for example. In FIG. 11, the niobium dopant element 23 is contained in the portions of the charge storage film 15 adjacent to of each film 12 and in the portions of the charge storage film 15 adjacent to each insulating film 19. That is, the niobium dopant element 23 is contained in the charge storage film 15 in the cell portions and in the charge storage film 15 in the inter-cell portions. The niobium dopant elements 23 are contained substantially uniformly within the charge storage film 15. The charge storage film 15 of the third embodiment is a SiN film to which the niobium dopant element 23 is added. Thus, the charge storage film can be said to comprise silicon, nitrogen, and niobium (dopant element 23). The charge storage film 15 of the third embodiment may further contain oxygen in some examples (e.g., niobium-doped silicon oxynitride).

In other examples, the charge storage film 15 of the third embodiment may contain a molybdenum (Mo) in place of, or along with niobium. In this case, the molybdenum atomic concentration in the charge storage film 15 and the presence of elements other than the molybdenum can be designed in the same manner as described for niobium (dopant element 23) above. Moreover, the semiconductor storage device of the third embodiment may include the dopant element 21 (boron) and/or dopant element 22 (deuterium) such as in the case of the semiconductor storage devices of the first embodiment and the second embodiment.

According to the third embodiment, by adding the niobium dopant element 23 to the charge storage film 15, it is possible to make the trap level in the charge storage film 15 deeper. Thus, it is preferable to add the niobium dopant element 23 to the charge storage film 15 in the cell portion and the inter-cell portion. Moreover, the higher the niobium concentration in the charge storage film 15 becomes, the closer to the properties of a metal layer the charge storage film 15 will obtain, therefore, it is preferable to set the Nb concentration in the charge storage film 15 at 1.0×10²¹ atoms/cm³ or less. The same goes for a case where the molybdenum is used in place of niobium.

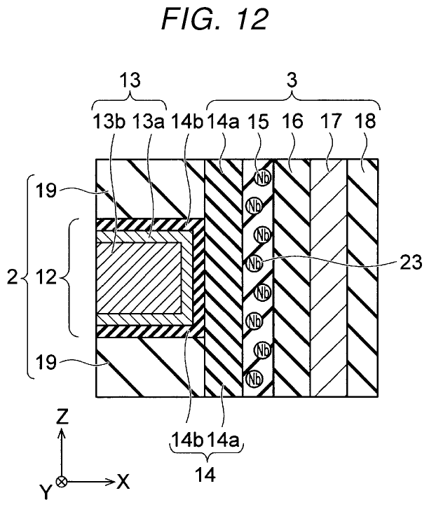

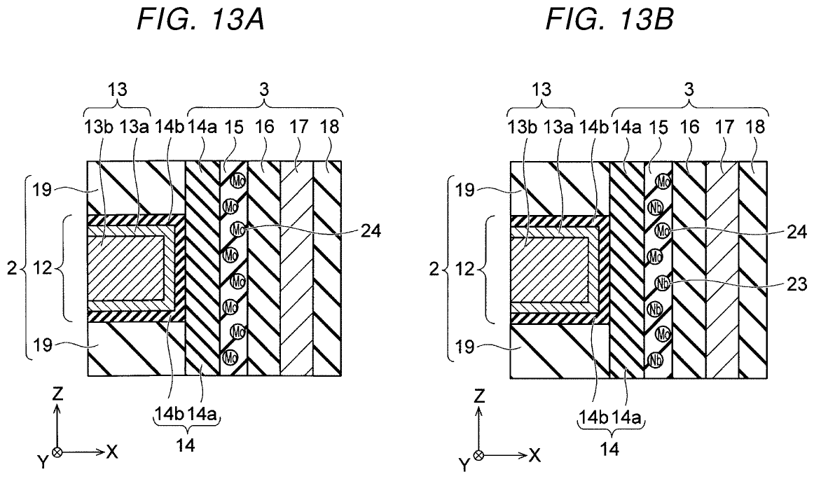

FIG. 12 and FIGS. 13A and 13B are cross-sectional views showing examples of the structure of the semiconductor storage device of the third embodiment.

In the example shown in FIG. 12, the dopant element 23 is contained in portion of the charge storage film 15 adjacent to the film 12 and also in the portion adjacent to the insulating film 19.

In the example shown in FIG. 13A, the charge storage film 15 contains a molybdenum dopant element 24 in place of the niobium dopant element 23. The distribution of molybdenum dopant element 24 in the charge storage film 15 matches the distribution in FIG. 12 for niobium.

In the example shown in FIG. 13B, the charge storage film 15 contains the molybdenum dopant element 24 along with the niobium dopant element 23. The distribution of these dopants in the charge storage film 15 matches the overall distribution of niobium in FIG. 12. The charge storage film 15 of the third embodiment may contain just one of niobium dopants or the molybdenum dopants or may contain both the molybdenum and niobium dopants.

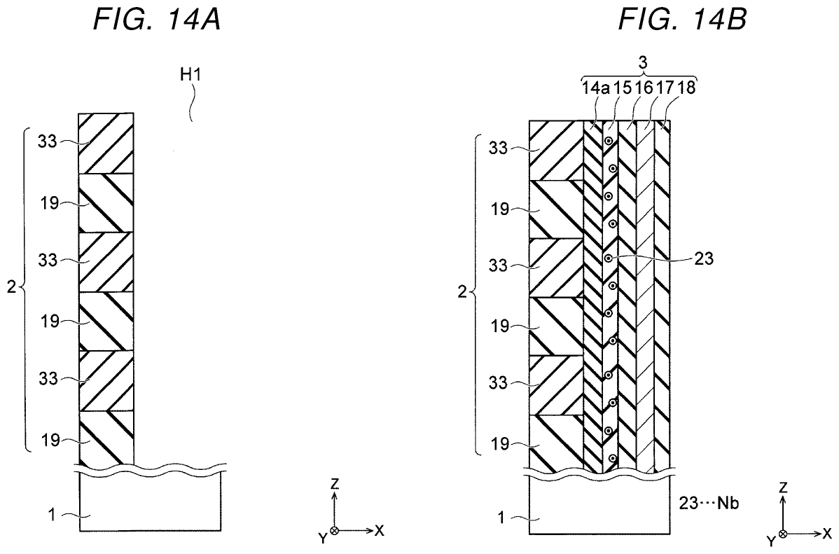

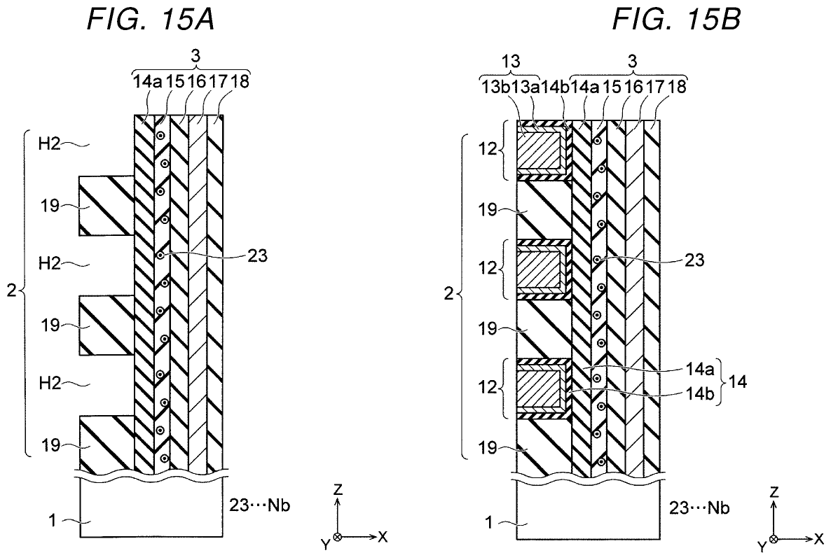

FIGS. 14A and 14B and FIGS. 15A and 15B are cross-sectional views showing aspects related to a method for fabricating the semiconductor storage device of the third embodiment.

First, a plurality of insulating films 19 and a plurality of sacrificial films 33 are alternately formed above a substrate 1 and a memory hole H1 is formed in the insulating films 19 and the sacrificial films 33 by lithography and RIE (FIG. 14A). The insulating film 19 is a SiO₂ film, for example. A film 12 eventually replaces each sacrificial film 33. The sacrificial film 33 is a SiN film, for example. The memory hole H1 is formed extending in the Z direction.

Next, an insulating layer 14a, a charge storage film 15, a tunnel insulating film 16, a channel semiconductor film 17, and a core insulating film 18 are formed in this order in the memory hole H1 (FIG. 14B). As a result, the columnar portion 3 is formed in the memory hole H1. The charge storage film 15 is formed on a side surface of each insulating film 19 and on a side surface of each sacrificial film 33 with the insulating layer 14a placed therebetween. The channel semiconductor film 17 is formed on a side surface of the charge storage film 15 with the tunnel insulating film 16 placed therebetween.

The charge storage film 15 is a silicon nitride (SiN) film having a film thickness of about 6 nm, for example, and is formed by ALD in a reduced-pressure environment at 300° C. or to 800° C. using dichlorosilane (SiH₂Cl₂) gas and ammonia (NH₃) gas. In the third embodiment, by supplying niobium pentachloride (NbCl₅), water (H₂O), and ammonia (NH₃) during the ALD sequence, the niobium dopant element 23 is added to the charge storage film 15. In this case, the niobium dopant element 23 is added to the charge storage film 15 in the form of niobium oxynitride (NbOₓN_{y}), for example. In the third embodiment, the molybdenum dopant element 24 may be added to the charge storage film 15 by supplying MoCl₅, NH₃, and zinc (Zn) during this ALD sequence. In this case, the molybdenum dopant element 24 is added to the charge storage film 15 in the form of molybdenum nitride (MoN_{y}), for example. The charge storage film 15 of the third embodiment is formed after the formation of the insulating layer 14a.

The tunnel insulating film 16 is a SiON film having a film thickness of about 7 nm, for example, and is formed by ALD in a reduced-pressure environment at 400° C. to 800° C. using HCD gas, NH₃ gas, and O₂ gas. The channel semiconductor film 17 is a silicon layer having a film thickness of about 10 nm, for example, and is formed by CVD in a reduced-pressure environment at 400° to 800° C. using silane (SiH₄) gas. The resulting film is then crystallized by annealing. This causes this silicon layer to change to a polysilicon layer from an amorphous silicon layer. The core insulating film 18 is a SiO₂ film, for example, and is formed by CVD using TEOS.

Then, an unillustrated slit is formed in the insulating films 19 and the sacrificial films 33 and the sacrificial films 33 are removed from the slit (FIG. 15A). As a result, a plurality of cavities H2 are formed between the insulating films 19 and the insulating layer 14a is exposed in these cavities H2.

Next, an insulating layer 14b, a barrier metal layer 13a, and an electrode material layer 13b are formed in order in each cavity H2 from the slit (FIG. 15B). As a result, a block insulating film 14 and an electrode film 13 are formed in order on a side surface of the charge storage film 15 and films 12 are formed. In this way, the sacrificial films 33 are replaced with the electrode films 13. The insulating layer 14b is an AlO, film having a film thickness of about 3 nm, for example, and is formed by ALD in a reduced-pressure environment at 200° C. to 500° C. using AlCl₃ gas and O₃ gas. The barrier metal layer 13a is a TiN film, for example, and is formed by CVD using titanium tetrachloride (TiCl₄) gas and ammonia (NH₃) gas. The electrode material layer 13b is a tungsten (W) layer, for example, and is formed by CVD using tungsten hexafluoride (WF6) gas.

Then, various insulating films, wiring layers, plug layers, and the like are formed on the substrate 1. For example, the previously formed slit is filled with an insulating film. In this way, the semiconductor storage device of the third embodiment is fabricated.

As described above, the charge storage film 15 of the present embodiment is formed so as to contain at least one of the niobium dopant element 23 and the molybdenum dopant element 24. Thus, according to the third embodiment, as described with reference to FIG. 11, it is possible to increase the performance of the charge storage film 15.

### Fourth Embodiment

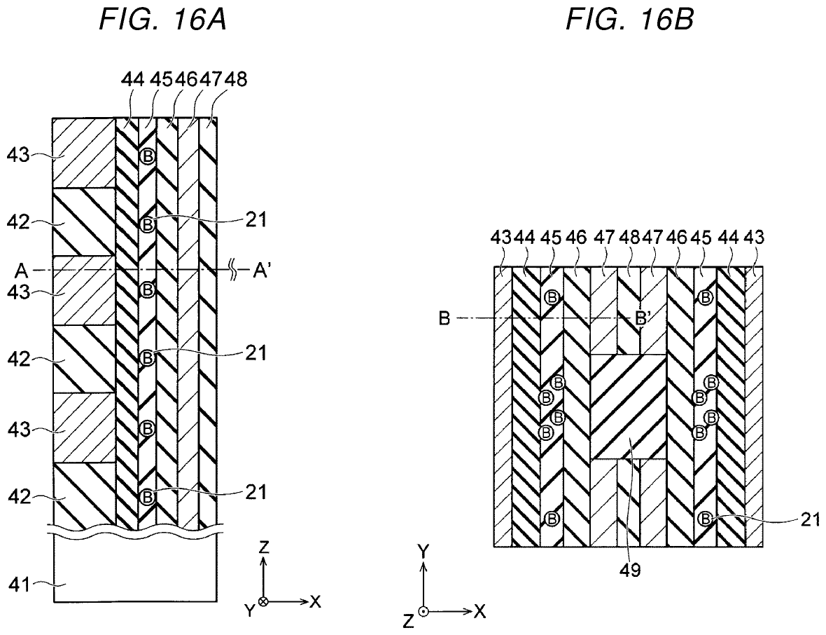

FIGS. 16A and 16B are cross-sectional views showing the structure of a semiconductor storage device of a fourth embodiment.

FIG. 16A shows a longitudinal section (an XZ section) of the semiconductor storage device of the present embodiment, and FIG. 16B shows a cross section (an XY section) of the semiconductor storage device of the present embodiment. FIG. 16B shows a cross section along the line A-A′ shown in FIG. 16A, and FIG. 16A shows a longitudinal section along the line B-B′ shown in FIG. 16B. A region shown in FIG. 16A corresponds to a part of a region shown in FIG. 16B. The semiconductor storage device of the present embodiment is three-dimensional semiconductor memory of a type different from the type of the semiconductor storage devices of the first to third embodiments, for example.

The semiconductor storage device of the present embodiment includes a substrate 41 and a plurality of stacked portions formed above the substrate 41, and, as shown in FIG. 16A, each of these stacked portions includes a plurality of insulating films 42 and a plurality of electrode films 43 which are alternately formed above the substrate 41. On the other hand, FIG. 16B shows two electrode films 43 in two stacked portions. FIG. 16A shows the left stacked portion of these two stacked portions.

The substrate 41 is a semiconductor substrate such as a silicon substrate, for example. FIGS. 16A and 16B show an X direction and a Y direction which are parallel to the front surface of the substrate 41 and are perpendicular to each other and a Z direction perpendicular to the front surface of the substrate 41.

The insulating films 42 extend in the Y direction. The insulating film 42 is a SiO₂ film, for example. The electrode films 43 also extend in the Y direction. The electrode films 43 include a TiN film as a barrier metal layer and include a W layer as an electrode material layer, for example.

As shown in FIG. 16A, the semiconductor storage device of the present embodiment further includes a block insulating film 44, a charge storage film 45, a tunnel insulating film 46, a channel semiconductor film 47, and a core insulating film 48 which are formed in order on a side surface of each insulating film 42 and each electrode film 43 of each stacked portion. FIG. 16B shows two block insulating films 44, two charge storage films 45, two tunnel insulating films 46, four channel semiconductor films 47, two core insulating films 48, and one insulating film 49 which are formed between the two stacked portions. The block insulating film 44 is an example of a first insulating film, the tunnel insulating film 46 is an example of a second insulating film, and the insulating film 49 is an example of a third insulating film.

The block insulating film 44, the charge storage film 45, and the tunnel insulating film 46 extend in the Y direction and the Z direction. The block insulating film 44 is a SiO₂ film, for example. The charge storage film 45 is a SiN film, for example. The tunnel insulating film 46 is a SiON film, for example.

The channel semiconductor film 47, the core insulating film 48, and the insulating film 49 extend in the Z direction. The two stacked portions share the core insulating film 48. The insulating film 49 is provided between the channel semiconductor films 47 which are adjacent to each other in the Y direction and between the core insulating films 48 which are adjacent to each other in the Y direction. The channel semiconductor film 47 is a polysilicon layer, for example. The core insulating film 48 is a SiO₂ film, for example. The insulating film 49 is a SiO₂ film, for example.

As described above, in the semiconductor storage device of the present embodiment, the electrode film 43 extends in the Y direction and the channel semiconductor film 47 extends in the Z direction. Thus, the electrode film 43 and the channel semiconductor film 47 intersect at predetermined Y coordinate and Z coordinate. A point at which the electrode film 43 and the channel semiconductor film 47 intersect will be referred to as a “point of intersection”. In the present embodiment, a region located at a point of intersection is a cell portion and a region displaced, in the Y direction, from the cell portion is an inter-cell portion.

In the present embodiment, the charge storage film 45 contains the dopant element 21 (boron). It is to be noted that, as shown in FIG. 16B, the boron concentration in portion of the charge storage film 45 between the electrode film 43 and the insulating film 49 is higher than the boron concentration in the portion of the charge storage film 45 between the electrode film 43 and the channel semiconductor film 47. Thus, the boron concentration in the charge storage film 45 in the inter-cell portion is higher than the boron concentration in the charge storage film 45 in the cell portion.

FIG. 16B shows a state in which the charge storage film 45 in the inter-cell portion contains the dopant element 21 (boron) in high concentrations and the charge storage film 45 in the cell portion contains the dopant element 21 (boron) in low concentrations.

The boron concentration in the charge storage film 45 in the inter-cell portion is 5.0×10²⁰ atoms/cm³ or more, for example. The boron concentration in the charge storage film 45 in the cell portion is 1.0×10¹⁹ atoms/cm³ or more but less than 5.0×10²⁰ atoms/cm³, for example. The charge storage film 45 in the cell portion may contain the dopant element 21 (boron), the charge storage film 45 does not otherwise have to contain the dopant element 21.

It is to be noted that, as in the case of the semiconductor storage device of the first, second, or third embodiment, the semiconductor storage device of the fourth embodiment may contain at least one of the dopant element 22 (deuterium), the niobium dopant element 23, and the molybdenum dopant element 24. In this case, the block insulating film 14, the charge storage film 15, the tunnel insulating film 16, the channel semiconductor film 17, and the core insulating film 18 of the first, second, or third embodiment respectively correspond to the block insulating film 44, the charge storage film 45, the tunnel insulating film 46, the channel semiconductor film 47, and the core insulating film 48 of the present embodiment. Moreover, the semiconductor storage device of the fourth embodiment may contain the dopant element 21 (boron) not only in the charge storage film 45, but also in the channel semiconductor film 47.

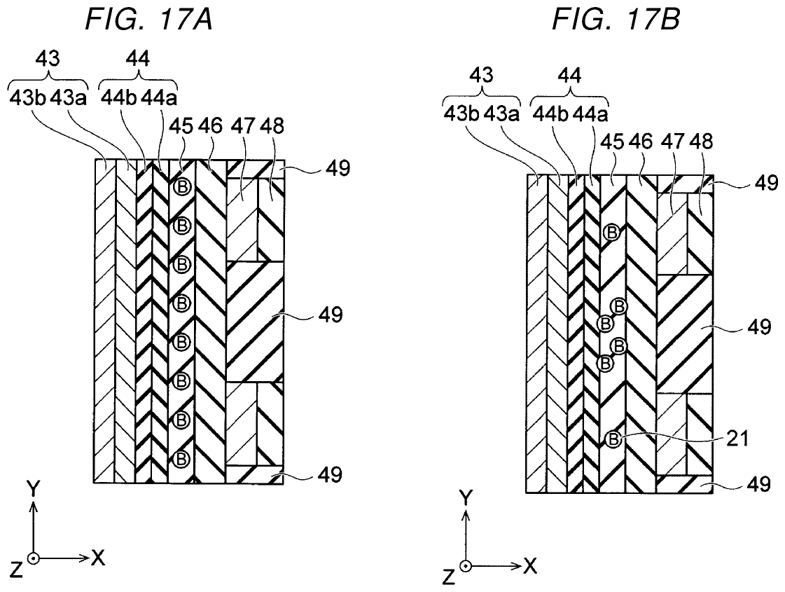

FIGS. 17A and 17B are cross-sectional views showing the structure of a semiconductor storage device of a comparative example of the fourth embodiment and the structure of the semiconductor storage device of the fourth embodiment.

FIG. 17A shows a cross section of the semiconductor storage device of the above-mentioned comparative example. In this comparative example, the B concentration in the charge storage film 45 in the inter-cell portion is equal to the B concentration in the charge storage film 45 in the cell portion.

According to this comparative example, by adding the Dopant element 21 to the charge storage film 45 in the inter-cell portion, it is possible to lower the dielectric constant of the charge storage film 45 in the inter-cell portion and reduce the capacitance of the inter-cell portion. This makes it possible to prevent interference between the memory cells and curb the spread of the distribution of the threshold voltages of the memory cells.

On the other hand, the charge storage film 45 in the cell portion of this comparative example contains the Dopant element 21 whose concentration is equal to the concentration of the Dopant element 21 in the charge storage film 45 in the inter-cell portion. When the charge storage film 45 in the cell portion contains a high concentration of the Dopant element 21, a defect occurs in the charge storage film 45 in the cell portion, which results in a dielectric strength failure and a decrease in reliability of the memory cell.

FIG. 17B shows a cross section of the semiconductor storage device of the present embodiment. In the present embodiment, the B concentration in the charge storage film 45 in the inter-cell portion is higher than the B concentration in the charge storage film 45 in the cell portion.

According to the present embodiment, by adding the Dopant element 21 to the charge storage film 45 in the inter-cell portion in high concentrations, as in the case of the above-mentioned comparative example, it is possible to lower the dielectric constant of the charge storage film 45 in the inter-cell portion and reduce the capacitance of the inter-cell portion. This makes it possible to prevent interference between the memory cells and curb the spread of the distribution of the threshold voltages of the memory cells. In the present embodiment, the B concentration in the charge storage film 45 in the inter-cell portion is 5.0×10²⁰ atoms/cm³ or more, for example.

Moreover, the B concentration in the charge storage film 45 in the cell portion of the present embodiment is lower than the B concentration in the charge storage film 45 in the inter-cell portion. This makes it possible to prevent a defect from occurring in the charge storage film 45 in the cell portion and prevent a dielectric strength failure and a decrease in reliability of the memory cell.

Furthermore, according to the present embodiment, by adding the Dopant element 21 to the charge storage film 45 in the cell portion in low concentrations, it is possible to make deeper the trap level in the charge storage film 45 in the cell portion. This makes it possible improve the write characteristic and charge retention property of the memory cell. In the present embodiment, the B concentration in the charge storage film 45 in the cell portion is in a range of 1.0×10¹⁹ atoms/cm³ to 5.0×10²⁰ atoms/cm³, for example.

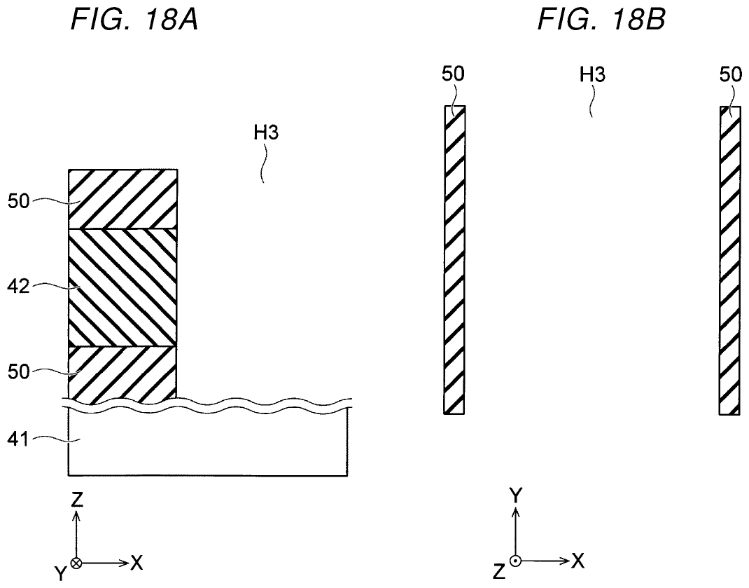

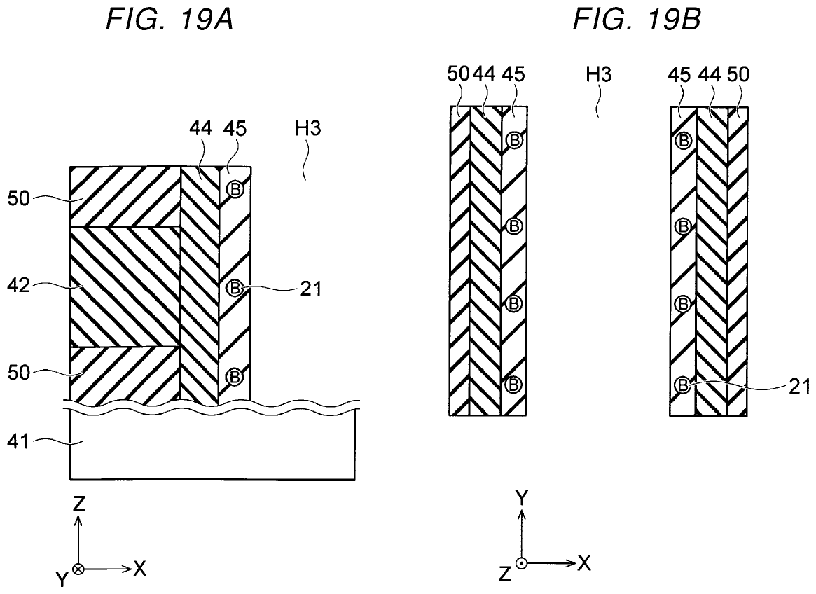

FIGS. 18A to 23B are cross-sectional views showing a method for fabricating the semiconductor storage device of the fourth embodiment. FIGS. 18A and 18B respectively show a longitudinal section and a cross section of the semiconductor storage device of the present embodiment. The same goes for FIGS. 19A to 23B.

First, a plurality of insulating films 42 and a plurality of sacrificial films 50 are alternately formed on a substrate 41, and a memory hole H3 is formed in the insulating films 42 and the sacrificial films 50 by lithography and RIE (FIGS. 18A and 18B). The insulating film 42 is a SiO₂ film having a film thickness of about 50 nm, for example, and is formed by CVD in a reduced-pressure environment (2000 Pa or less) at 300° C. to 700° C. using TEOS as a precursor gas. An electrode film 43 is formed in place of the sacrificial film 50 in a process which will be described later. The sacrificial film 50 is a SiN film having a film thickness of about 50 nm, for example, and is formed by CVD in a reduced-pressure environment (2000 Pa or less) at 300° C. to 850° C. using SiH₂Cl₂ gas and NH₃ gas. The memory hole H3 is formed extending in the Y direction and the Z direction.

Next, a block insulating film 44 and a charge storage film 45 are formed in this order in the memory hole H3 (FIGS. 19A and 19B). As a result, the block insulating film 44 is formed on a side surface of each insulating film 42 and also a side surface of each sacrificial film 50. The charge storage film 45 is formed on a side surface of each insulating film 42 and a side surface of each sacrificial film 50 with the block insulating film 44 placed therebetween. The block insulating film 44 is a silicon oxide (SiO₂) film having a film thickness of about 7 nm, for example, and is formed by ALD in a reduced-pressure environment (2000 Pa or less) at 400° C. to 800° C. using O₃ gas and tris(dimethylamino)silane (“TDMAS”) gas.

The charge storage film 45 is a SiN film having a film thickness of about 7 nm, for example, and is formed by ALD in a reduced-pressure environment (2000 Pa or less) at 300° C. to 800° C. using SiH₂Cl₂ gas and NH₃ gas. In the present embodiment, by supplying BCl₃ gas during this ALD sequence, the dopant element 21 (boron) is added to the charge storage film 45. The addition of the boron to the charge storage film 45 is performed by, for example, adding the dopant element 21 (boron) to the front surface of the charge storage film 45 and thermally diffusing the dopant element 21 (boron) into the charge storage film 45. At the stage of FIGS. 19A and 19B, the B concentration in the charge storage film 45 is uniform.

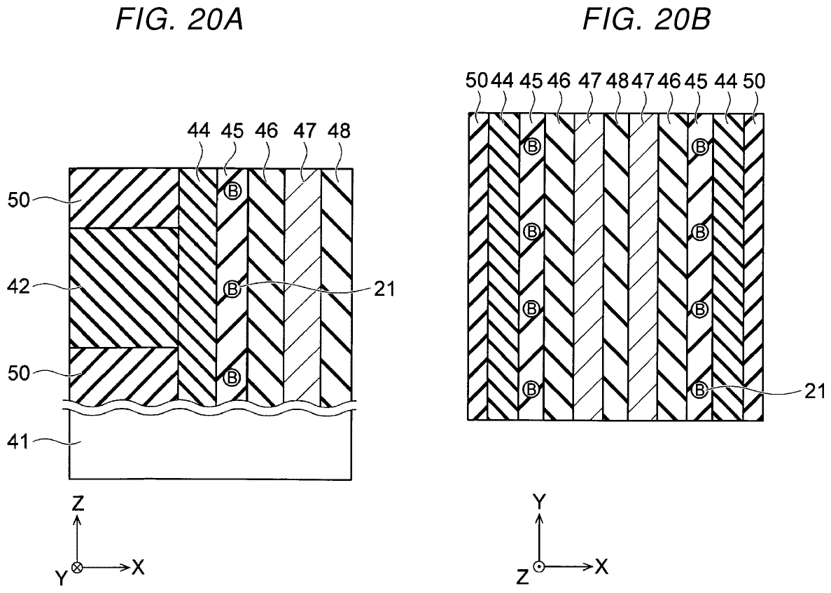

Then, a tunnel insulating film 46, a channel semiconductor film 47, and a core insulating film 48 are formed in order in the memory hole H3 (FIGS. 20A and 20B). As a result, the tunnel insulating film 46 is formed on a side surface of the charge storage film 45, and the channel semiconductor film 47 is formed on the side surface of the charge storage film 45 with the tunnel insulating film 46 placed therebetween. Furthermore, the core insulating film 48 is formed on a side surface of the channel semiconductor film 47.

The tunnel insulating film 46 is a SiON film having a film thickness of about 6 nm, for example, and is formed by ALD in a reduced-pressure environment (2000 Pa or less) at 400° C. to 800° C. or lower using hexachlorodisilane (“HCD”) gas, NH₃ gas, and O₂ gas. The channel semiconductor film 47 is a silicon layer having a film thickness of about 10 nm, for example, and is formed by CVD in a reduced-pressure environment (2000 Pa or less) at 400° C. to 800° C. using SiH₄ gas. The resulting film is then crystallized by annealing. This causes this silicon layer to change to a polysilicon layer from an amorphous silicon layer. The core insulating film 48 is a SiO₂ film, for example, and is formed by CVD using TEOS.

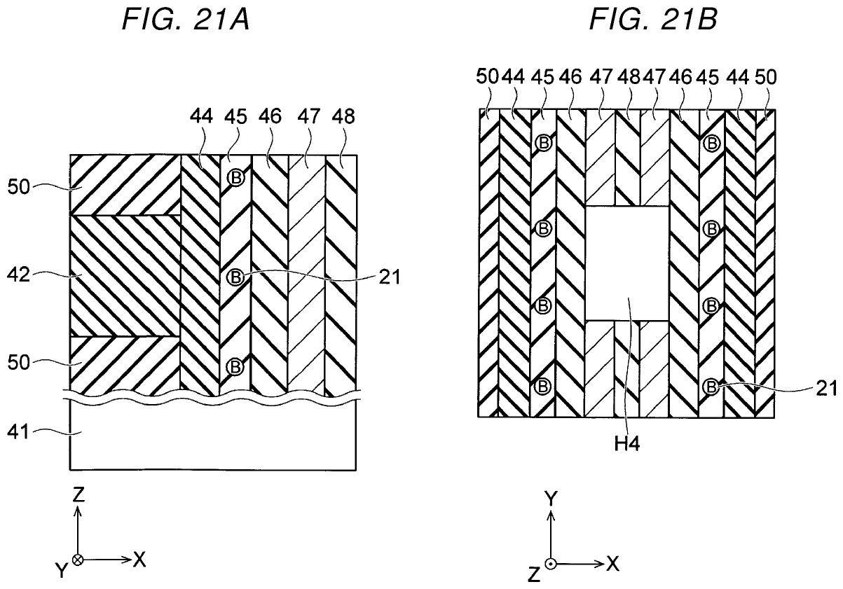

Next, a hole H4 is formed in the channel semiconductor film 47 and the core insulating film 48 by lithography and RIE (FIGS. 21A and 21B). As a result, each of the channel semiconductor film 47 and the core insulating film 48 is divided into a plurality of portions along the Z direction . The hole H4 is formed extending in the Z direction.

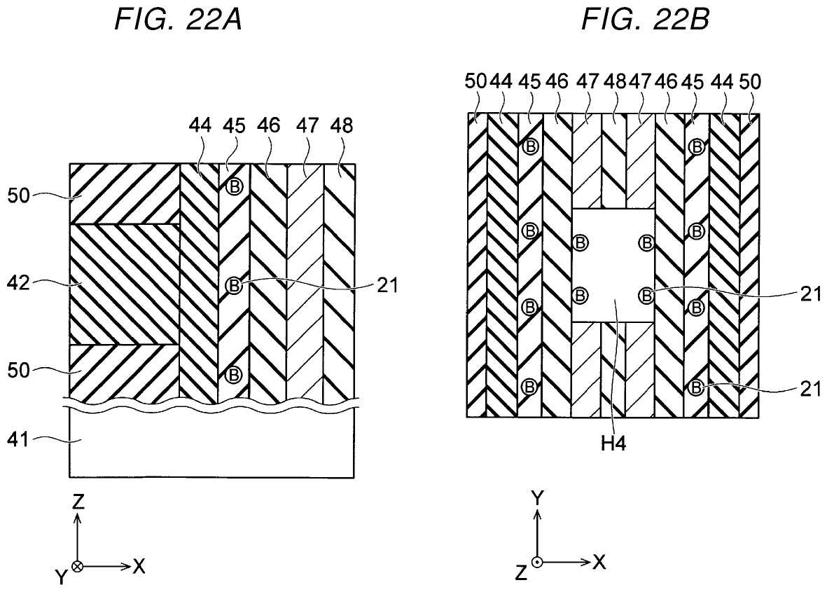

Then, BCl₃ gas is supplied to the inside of the hole H4 (FIGS. 22A and 22B). As a result, BCl₃ molecules adsorb onto a side surface of the tunnel insulating film 46 that is exposed in the hole H4.

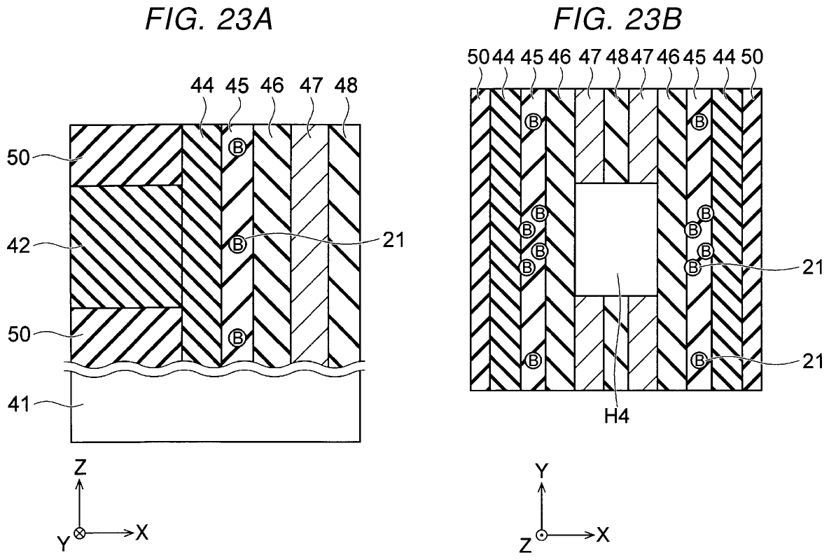

Next, the dopant element 21 (boron) in the BCl₃ molecules is thermally diffused in the charge storage film 45 (FIGS. 23A and 23B). This makes it possible to make the boron concentration in the charge storage film 45 in the inter-cell portion higher than the boron concentration in the charge storage film 45 in the cell portion. The B concentration in the charge storage film 45 in the inter-cell portion is 5.0×10²⁰ atoms/cm³ or more, for example. The boron concentration in the charge storage film 45 in the cell portion is 1.0×10¹⁹ atoms/cm³ or more but less than 5.0×10²⁰ atoms/cm³, for example. It is to be noted that, at the stage of FIGS. 23A and 23B, the cell portion and the inter-cell portion are defined by the relationship between the sacrificial film 50 and the channel semiconductor film 47 instead of the relationship between the electrode film 43 and the channel semiconductor film 47.

Then, various insulating films, wiring layers, plug layers, and the like are formed on the substrate 41. For example, the hole H4 is filled with an insulating film 49 and the sacrificial films 50 are replaced with the electrode films 43 (FIGS. 16A and 16B). When the sacrificial film 50 is removed, the electrode film 43 may be formed in a space, which is left by the removal of the sacrificial film 50, with an AlO film (a block insulating film) placed between the inner surface of the space and the electrode film 43. In this way, the semiconductor storage device of the fourth embodiment is fabricated.

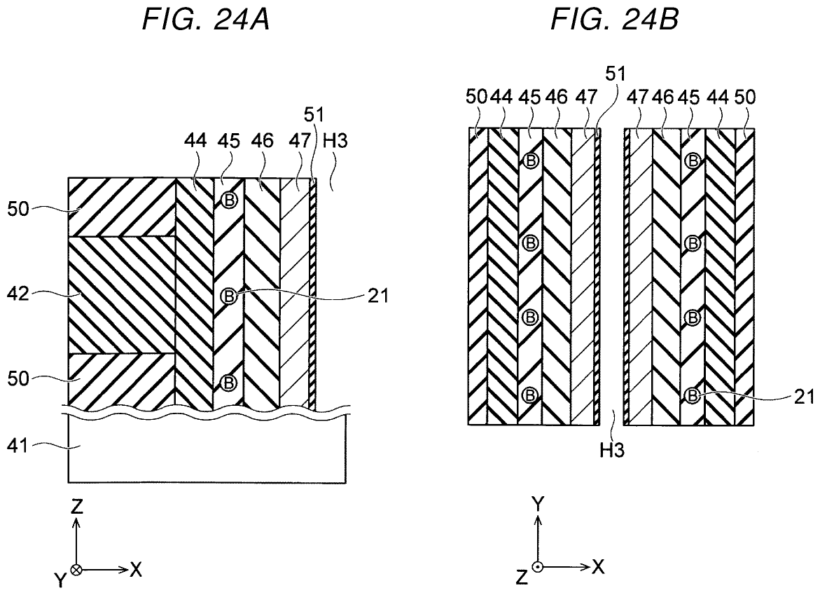

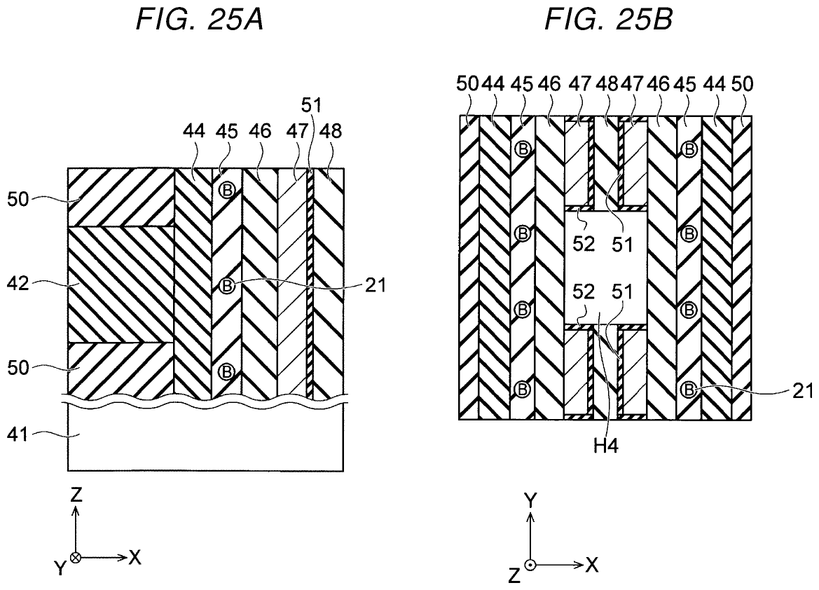

FIGS. 24A and 24B and FIGS. 25A and 25B are cross-sectional views showing aspects related to a method for fabricating a semiconductor storage device of a modified example of the fourth embodiment.

First, in this modification the processes shown in FIGS. 18A to 19B are performed as before. Next, a tunnel insulating film 46 and a channel semiconductor film 47 are formed in this order in the memory hole H3, then a side surface of the channel semiconductor film 47 is nitrided using N₂ radicals (FIGS. 24A and 24B). As a result, a nitride film 51 is formed on the side surface of the channel semiconductor film 47. For example, the channel semiconductor film 47 is a silicon layer and the nitride film 51 is a SiN film. As shown in FIG. 24A, the nitride film 51 is formed on the side surface of the channel semiconductor film 47 on the side opposite to the charge storage film 45. The nitride film 51 may be formed by thermal nitridation which is performed at 600° C. or higher using NH₃ gas or ND₃ (deuterated ammonia) gas. The nitride film 51 is an example of a fourth insulating film.

Then, a core insulating film 48 is formed in the memory hole H3, and a hole H4 is formed in the channel semiconductor film 47 and the core insulating film 48 by lithography and RIE. A side surface of the channel semiconductor film 47 is then nitrided using N₂ radicals (FIGS. 25A and 25B). As a result, a nitride film 52 is formed on the side surface of the channel semiconductor film 47. For example, the channel semiconductor film 47 is a silicon layer and the nitride film 52 is a SiN film. The nitride film 52 may be formed by thermal nitridation which is performed at 600° C. or higher using NH₃ gas or ND₃ gas. The nitride film 52 is also an example of the fourth insulating film.

Next, the processes shown in FIGS. 22A to 23B are performed as before. Then, various insulating films, wiring layers, plug layers, and the like are formed on the substrate 41. For example, the hole H4 is filled with an insulating film 49, and the sacrificial films 50 are replaced with electrode films 43 (FIGS. 16A and 16B). When the sacrificial film 50 is removed, the electrode film 43 may be formed in a space, which is left by the removal of the sacrificial film 50, with an AlOₓ film (a block insulating film) placed between the inner surface of the space and the electrode film 43. In this way, the semiconductor storage device of this modified example is fabricated.

As described above, the charge storage film 45 of the fourth embodiment is formed such that the B concentration in the charge storage film 45 portion between the electrode film 43 and the insulating film 49 is higher than the B concentration in the charge storage film 45 portion between the electrode film 43 and the channel semiconductor film 47. That is, the B concentration in the charge storage film 45 has a non-constant distribution along the Y direction. The B concentration of the charge storage film 45 between the electrode film 43 and the insulating film 49 is higher than the B concentration of the charge storage film 45 between the electrode film 43 and the channel semiconductor film 47. As a result, the B concentration in the charge storage film 45 in the inter-cell portion is higher than the B concentration in the charge storage film 45 in the cell portion. Thus, according to the fourth embodiment, as described with reference to FIGS. 17A and 17B, it is possible to increase the performance of the charge storage film 45.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a plurality of electrode films stacked on a substrate, the plurality of electrode films being spaced from each other by a plurality of gaps or a plurality of insulating layers;
a charge storage film on a side surface of each of the plurality of electrode films with a first insulating film therebetween; and
a semiconductor film on a side surface of the charge storage film with a second insulating film therebetween, wherein
a concentration of a first element in the charge storage film adjacent to the gaps or the insulating layers is higher than a concentration of the first element in the charge storage film adjacent to electrode films, and
the first element is one of boron, niobium, or molybdenum.

2. The semiconductor storage device according to claim 1, wherein
the first element is boron,
an atomic concentration of the first element in the charge storage film adjacent to each gap or each insulating layer is 5.0×10²⁰ atoms/cm³ or more, and
an atomic concentration of the first element in the charge storage film adjacent to each electrode film is between 1.0×10¹⁹ atoms/cm³ and 5.0×10²⁰ atoms/cm³.

3. The semiconductor storage device according to claim 1, wherein at least one of the first insulating film, the charge storage film, the second insulating film, and the semiconductor film contains deuterium.

4. The semiconductor storage device according to claim 3, wherein a deuterium concentration is higher than a hydrogen concentration in at least one of the first insulating film, the charge storage film, the second insulating film, and the semiconductor film.

5. The semiconductor storage device according to claim 1, wherein
the first element is niobium or molybdenum, and
a concentration of the first element in the charge storage film is 1.0×10²¹ atoms/cm³ or less.

6. The semiconductor storage device according to claim 1, wherein the charge storage film contains niobium or molybdenum in portions adjacent to each electrode film.

7. The semiconductor storage device according to claim 6, wherein the charge storage film contains oxygen and nitrogen.

8. A semiconductor storage device, comprising:
a plurality of electrode films stacked on a substrate with a plurality of insulating layers between adjacent electrode films, the electrode films and the insulating layers extending in a first direction;
a first insulating film on a side surface of each of the plurality of electrode films and extending in a second direction orthogonal to the first direction;
a charge storage film on a side surface of the first insulating film and extending in the second direction;
a second insulating film on a side surface of the charge storage film and extending in the second direction;
a plurality of semiconductor films, each semiconductor film being on a side surface of the second insulating film and extending in the second direction; and
a third insulating film on a side surface of the second insulating film between the semiconductor films and extending in the second direction, wherein
a concentration of a first element in the charge storage film between each electrode film and the third insulating film is higher than a concentration of the first element in the charge storage film between each electrode film and each semiconductor film, and
the first element is boron.

9. The semiconductor storage device according to claim 8, wherein the semiconductor film also contains boron.

10. The semiconductor storage device according to claim, further comprising:
a fourth insulating film on a side surface of each semiconductor film on opposite the charge storage film, the fourth insulating film containing nitrogen.

11. A method for fabricating a semiconductor storage device, the method comprising:
alternately forming first films and second films on a substrate;
forming a charge storage film on a side surface of each of the first and second films with a first insulating film therebetween; and
forming a semiconductor film on a side surface of the charge storage film with a second insulating film therebetween, wherein
a concentration of a first element in a portion of the charge storage film formed adjacent to the second film is higher than a concentration of the first element in a portion of the charge storage film formed adjacent to the first film, and
the first element is boron, niobium, or molybdenum.

12. The method according to claim 11, wherein
the first films are replaced with electrode layers, and
boron is added to the charge storage film before or after the first films are replaced.

13. The method according to claim 11, wherein
the plurality of second films are removed and a plurality of gaps are formed, and
the boron is added to the charge storage film before or after the formation of the plurality of gaps.

14. The method according to claim 11, further comprising:
forming a fourth insulating film containing nitrogen by nitriding a side surface of the semiconductor film.

15. The method according to claim 11, further comprising:
adding deuterium to at least one of the first insulating film, the charge storage film, the second insulating film, the semiconductor film.

16. The method according to claim 15, wherein the addition of deuterium is performed before a plurality of electrode films are formed in spaces left by removal of the first films.

17. The method according to claim 15, wherein the addition of deuterium is performed by annealing in a deuterium plasma.

18. The method according to claim 17, wherein the addition of deuterium is performed by the annealing using a radical component and an ion component.

19. The method according to claim 15, wherein the addition of the deuterium is performed by a treatment using D₂ gas and at least one of oxygen gas, helium (gas, neon gas, argon gas, krypton gas, xenon gas, or radon gas.
